(19) United States
(12) Patent Application Publication
(10) Pub. No.: US 2010/0188773 A1
(43) Pub. Date: Jul. 29, 2010

(54) Multiferroic Storage Medium

(75) Inventors: Florin Zavaliche, Cranberry Township, PA (US); Tong Zhao, Cranberry Township, PA (US); Philip George Pitcher, Shakopee, MN (US); Michael Allen Seigler, Pittsburgh, PA (US)

Correspondence Address: PIETRAGALLO GORDON ALFANO BOSICK & RASPANTI, LLP, ONE OXFORD CENTRE, 38TH FLOOR, 301 GRANT STREET, PITTSBURGH, PA, 15219-6404, US

(73) Assignee: Seagate Technology LLC, Scotts Valley, CA (US)

(21) Appl. No.: 12/361,762

(22) Filed: Jan. 29, 2009

(51) Int. Cl. G11B 5/33; G11C 11/22

(52) U.S. Cl. 360/110; 365/145; G9B/5.104

(57) ABSTRACT

A data storage medium that includes a multiferroic thin film and ferromagnetic storage domains formed in the multiferroic thin film. The multiferroic thin film may be formed of at least one of BiFeO₃, or any other ferroelectric and antiferromagnetic material. The ferromagnetic storage domains may be formed in the multiferroic thin film by an ion implantation process. A data storage system that incorporates the data storage medium is also provided.

### BACKGROUND

Attempts to increase the capacity of magnetic data storage devices must balance writability, grain size and magnetic anisotropy in the magnetic data storage media. Write heads can only generate a limited magnetic field, and this limit is set by the maximum volume magnetization that can be achieved in a material, the maximum current density that can be put through a conductor, and the head-to-media separation. If the anisotropy in the media is lowered to the point where it can be written by the write head and the grains are made small enough to maintain an acceptable signal-to-noise ratio, the media may not be thermally stable for large areal densities. This is referred to as the superparamagnetic limit.

Ferroelectric (FE) data storage media has the advantage that it is written using an electric field, and very large electric field values can be generated with a thin-film device. Thus, FE media with a very large anisotropy can be written by a thin-film device, and a thermally stable FE media with very small domains (and narrow domain walls) can be written.

Multiferroics (materials with multiple order parameters like spontaneous FE distortion and magnetic ordering) are attractive materials because several functionalities can be integrated in the same device. The multiferroic materials which simultaneously show FE and magnetic ordering are also called ferroelectromagnets. Single phase multiferroics usually exhibit transition temperatures well below room temperature, and weak remanent FE and magnetic polarization which make them impractical. One exception is BiFeO₃ which possesses transition temperatures well above room temperature, a high switchable ferroelectric polarization but a vanishing remanent magnetization due to the antiferromagnetic ordering. A reasonably large remanent magnetization is required either for magnetoresistive readback from a media disc, or to polarize the current carrying electrons for magnetization orientation detection in a solid state memory device. Composite multiferroics such as the vertical, self-assembled, epitaxial three dimensional heterostructures show strong ferroic properties, but are difficult to fabricate and lack long range order as needed, for example, for data storage media. Further, the typical domain size in composite multiferroics is about 100 nm, while a bit size of less than 10 nm is required for high density data storage. Domain refers to a single ferroic inclusion (either FE or magnetic) in a single ferroic matrix (either FE or magnetic). Thus, it is highly desirable to create single phase multiferroic materials with robust FE and magnetic ordering at room temperature.

### SUMMARY

An aspect of the present invention is to provide a data storage medium that includes a multiferroic thin film and ferromagnetic storage domains formed in the multiferroic thin film. The multiferroic thin film may be formed of at least one of BiFeO₃, or any other ferroelectric and antiferromagnetic material. The ferromagnetic storage domains may be formed in the multiferroic thin film by an ion implantation process.

Another aspect of the present invention is to provide a data storage system that includes a recording head and a data storage medium adjacent to the recording head. The data storage medium includes a multiferroic thin film and ferromagnetic storage domains formed in the multiferroic thin film. The multiferroic thin film may be formed of at least one of BiFeO₃, or any other ferroelectric and antiferromagnetic material. The ferromagnetic storage domains may be formed in the multiferroic thin film by an ion implantation process.

A further aspect of the present invention is to provide a bit patterned multiferroic storage medium that includes a layer of multiferroic material and ferromagnetic storage domains formed in the layer of multiferroic material.

These and various other features and advantages will be apparent from a reading of the following detailed description.

### DRAWINGS

FIG. 1 is a schematic illustration of a data storage medium, in accordance with an aspect of the invention.

FIG. 2 is a schematic illustration of a data storage system, in accordance with an aspect of the invention.

### DETAILED DESCRIPTION

In one aspect, the invention relates to switchable ferroelectric and spontaneous magnetization from single-phase multiferroic materials such as, for example, BiFeO₃ by local ion-implantation. Ion implantation of a thin multiferroic film through a lithographic mask will create a pattern of high remanent magnetization pillars or domains that may be used for data storage. The impinging ions would disrupt the spiral antiferromagnetic order (G-type) and would give rise to patches of non-zero net magnetization in the form of embedded pillars. The strong coupling between ferroelectricity and antiferromagnetism in the parent multiferroic material will lead to a strong coupling between ferroelectricity in the unimplanted matrix and magnetic order in the implanted regions. This coupling effect is mediated by the strong exchange interaction between the localized spins in the unimplanted and implanted areas.

In one aspect, the invention provides for the fabrication of multiferroic materials with high ferroelectric and magnetic polarizations from single-phase antiferromagnetic and ferroelectric films by an ion implantation process. Such engineered materials can be employed, for example, as storage media, where each of the implanted areas will store information in the form of e.g. up or down magnetization as in bit-patterned media. The patches are lithographically defined and therefore long-range order can be readily achieved, in contrast to the self-assembled ferroelectric-ferrimagnetic bit-patterned media. The long-range order in bit-patterned media is desirable for any storage scheme involving a spinning disk (e.g. hard disk drive) or fixed medium (e.g. solid state disk). The invention also provides for eliminating the need for highly magnetostrictive materials for an EAMR (electrically-assisted magnetic recording) scheme, since the magnetoelectric coupling is in this case mediated by the exchange interaction and not by stress. Further, given the possibility of tuning the implantation conditions, one may also create embedded magnetic spheres in the ferroelectric-antiferromagnetic matrix. In addition, since the pillars magnetization is pinned by the matrix antiferromagnetic order, there is no requirement for the minimum pillar size and Kᵤ to stabilize the ferromagnetic order.

In accordance with an aspect of the invention, a single-phase material with room temperature ferroelectric and antiferromagnetic order could be engineered to exhibit enhanced spontaneous magnetization through an appropriate ion implantation process. First, ion implantation may break the antiferromagnetic order by breaking the transition metal-oxygen-transition metal bonds which are responsible for the onset of the super-exchange interaction. Second, new structural/chemical phases with large room temperature net magnetization can form by a post implantation process such as thermal annealing, or during the implantation process. If this is performed with e.g. Fe, Ni, Co, or Mn ions, or any other suitable ions, the desired magnetic phase may form without relying on a post-implantation process. Furthermore, ion implantation with additional non-magnetic species such as Pt, or Cr may be beneficial for the stabilization of the desired ferromagnetic phases. A uniform concentration profile of the implanted species along the implantation direction is needed, which can be achieved by varying the ion implant parameters.

Since the high net magnetization phase (“pillars”) is fabricated from, and adjacent to the “bulk” antiferromagnetic material, they may strongly interact with each other through magnetic exchange. This will result in a pinning of the pillars' magnetization, whose switching can be assisted by locally altering the surrounding antiferromagnetic configuration through magnetoelectric coupling to the ferroelectric order. The application of an electric field changes the direction of ferroelectric polarization, which alters the antiferromagnetic configuration. A weak magnetic field can be superimposed on the electric field to align the pillars magnetization along the desired direction.

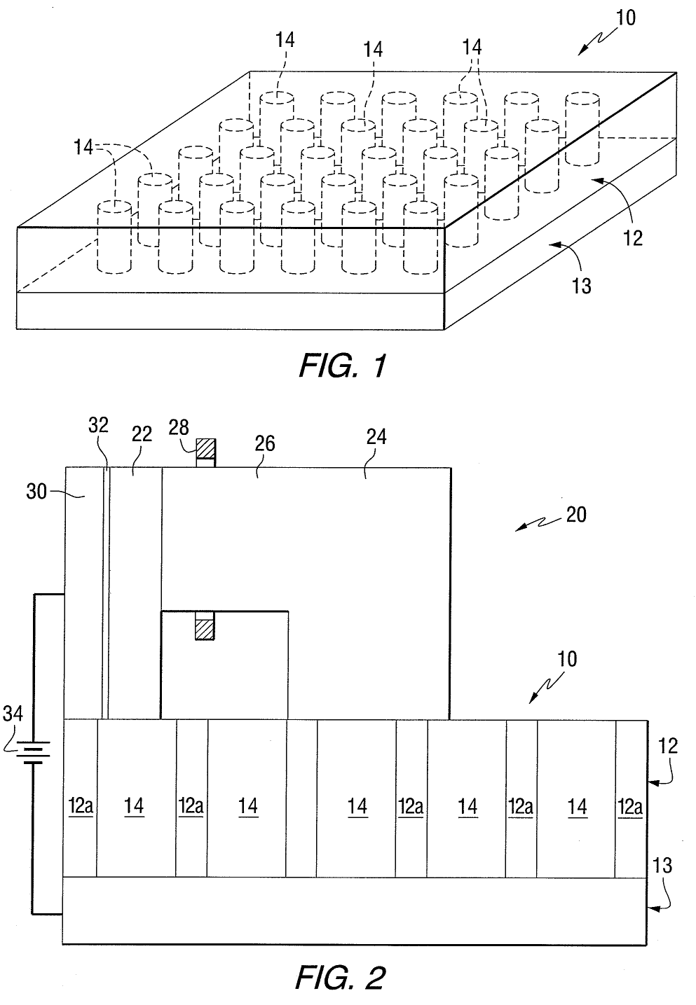

FIG. 1 is a schematic illustration of a data storage medium 10, in accordance with an aspect of the invention. In one aspect of the invention, the data storage medium 10 may be a bit patterned storage medium. In another aspect of the invention, the data storage medium 10 may be a multiferroic bit patterned storage medium.

Still referring to FIG. 1, the data storage medium 10 includes a layer 12 of a multiferroic material. The medium 10 also includes a plurality of ferromagnetic storage domains 14, generally represented by the “pillars” that are formed in the layer 12 of multiferroic material by an ion implantation process as explained herein. The domains 14 are spaced apart by regions 12a (see FIG. 2) of the multiferroic material that forms the layer 12. The medium 10 also may include a substrate 13 formed of, for example SrTiO₃-buffered Si on which the layer 12 is formed. The substrate 13 may include a soft magnetic layer formed thereon which allows the return of magnetic flux generated by the head. The layer 12 of multiferroic material may be formed of at least one of BiFeO₃, or any other ferroelectric and antiferromagnetic material. In one aspect of the invention, the layer 12 is ferroelectric. In another aspect of the invention, the layer 12 is antiferromagnetic. In another aspect of the invention, the layer 12 is antiferromagnetic and ferroelectric. The layer 12 of multiferroic material may be formed by, for example, a physical or chemical vapor deposition process such as sputtering, pulsed laser deposition, or chemical vapor deposition.

Still referring to FIG. 1, the ferromagnetic storage domains 14 that are implanted in the layer 12 of multiferroic material may store information in the form of, for example, “up” or “down” magnetization state such that the information may be written to the data storage medium 10 for storage and the information stored in the domains 14 may be read by a readback process. The ferromagnetic storage domains 14 may be formed of at least one of Fe, Co, Ni, Mn, or alloys of these such as FePt or CoCrPt.

As stated, the ferromagnetic storage domains 14 are implanted in the layer 12 of multiferroic material by an ion implantation process. Ion implantation is a non-equilibrium technique in which atoms are introduced into the surface region of a target (substrate) material through irradiation with charged particles accelerated to hyperthermal energies. The process is unlimited by thermodynamic considerations allowing the introduction of dopants (or defect/damage centers) at concentrations and distributions that would otherwise be unattainable, offering potentially unique materials engineering capabilities. Upon implantation, ions are brought to rest by losing their translational energy through a series of independent binary interactions with substrate atoms. Energy is essentially lost elastically through collisions between atomic nuclei and inelastically to their electron clouds. The distribution of implanted or displaced substrate atoms produced by ion implantation is described statistically by the projected range and straggle defined by the peak and width of a Gaussian distribution respectively.

FIG. 2 is a schematic illustration of a portion of an apparatus, e.g., a data storage system, constructed in accordance with an aspect of the invention. The apparatus includes a recording head 20 positioned adjacent to the data storage medium 10. In one aspect of the invention, the recording head 20 is in contact with the data storage medium 10. The recording head 20 includes a write pole 22 and a return pole 24. The write pole 22 and the return pole 24 are magnetically coupled by a yoke 26. Electric current in a coil 28 is used to create magnetic flux that extends from the write pole 22, through the media 10, and to the return pole 24. An electrode 30 is positioned near the write pole 22. In this example, the electrode 30 is electrically insulated from the write pole 22 by a layer of insulating material 32. A voltage source 34 is connected to the electrode 30, and in this example, to the media 10. The voltage source establishes a voltage between the electrode 30 and the media 10, thereby subjecting the media 10 to an electric field. The electric field may be turned on and off so that it is only on during writing. The applied electric field will switch the ferroelectric polarization in the multiferroic regions 12a. Because of the intrinsic coupling between the ferroelectric and antiferromagnetic domains in the multiferroic region 12a, the antiferromagnetic state will be affected, too. Since the magnetic domains 14 formed by ion implantation are in intimate contact with the antiferromagnetic domains in regions 12a, the former will experience a strong magnetic exchange interaction with the latter, which results in a change of magnetization direction and/or magnetic anisotropy in domains 14 as the electric field is applied. The weak magnetic field applied concomitantly to the electric field is generated by the write pole 22 and is needed to overcome additional energy barriers which may prevent the magnetic domains 14 to orient along the desired direction.

Accordingly, it will be appreciated that in accordance with an aspect of the invention, the recording head 20 illustrated in FIG. 2 includes a magnetic field write component and an electric field write component. Both components work in association with the data storage medium 10 as described herein in order to provide a data storage system having, for example, a multiferroic bit patterned data storage medium. Data may be retrieved in a similar manner as in a conventional magnetic hard disc drive readback scheme.

The implementation described above and other implementations are within the scope of the following claims.

What is claimed is:

1. A data storage medium, comprising:
a multiferroic thin film; and
ferromagnetic storage domains formed in the multiferroic thin film.

2. The data storage medium of claim 1, wherein the multiferroic thin film is BiFeO₃.

3. The data storage medium of claim 1, wherein the multiferroic thin film is ferroelectric.

4. The data storage medium of claim 1, wherein the multiferroic thin film is antiferromagnetic.

5. The data storage medium of claim 1, wherein the ferromagnetic storage domains are formed in the multiferroic thin film by ion implantation.

6. The data storage medium of claim 1, wherein the ferromagnetic storage domains are formed of at least one of Fe, Co, Ni, and Mn.

7. The data storage medium of claim 1 configured as a bit patterned storage medium.

8. A data storage system, comprising:
a recording head;
a data storage medium adjacent to the recording head, the data storage medium comprising:
a multiferroic thin film; and
ferromagnetic storage domains formed in the multiferroic thin film.

9. The data storage system of claim 8, wherein the multiferroic thin film is BiFeO₃.

10. The data storage system of claim 8, wherein the multiferroic thin film is ferroelectric.

11. The data storage system of claim 8, wherein the multiferroic thin film is antiferromagnetic.

12. The data storage system of claim 8, wherein the ferromagnetic storage domains are formed in the multiferroic thin film by ion implantation.

13. The data storage system of claim 8, wherein the ferromagnetic storage domains are formed of at least one of Fe, Co, Ni, and Mn.

14. The data storage system of claim 8 configured and arranged as a bit patterned storage medium.

15. The data storage system of claim 8, wherein the recording head includes a magnetic field write component.

16. The data storage system of claim 8, wherein the recording head includes an electric field write component.

17. The data storage system of claim 8, wherein the recording head includes a magnetic field write component and an electric field write component.

18. A bit patterned multiferroic storage medium, comprising:
a layer of multiferroic material; and
ferromagnetic storage domains formed in the layer of multiferroic material.

19. The bit patterned multiferroic storage medium of claim 18, wherein the multiferroic material is BiFeO₃.

20. The bit patterned multiferroic storage medium of claim 18, wherein the ferromagnetic storage domains are formed in the layer of multiferroic material by ion implantation.
